(19) United States
(12) Patent Application Publication
(10) Pub. No.: US 2016/0225956 A1
(43) Pub. Date: Aug. 4, 2016

(54) GROUP III NITRIDE SEMICONDUCTOR LIGHT-EMITTING DEVICE

(71) Applicant: TOYODA GOSEI CO., LTD., Kiyosu-shi (JP)

(72) Inventors: Takashi KAWAI, Kiyosu-shi (JP); Koichi GOSHONOO, Kiyosu-shi (JP); Kosuke YAHATA, Kiyosu-shi (JP)

(21) Appl. No.: 15/008,344

(22) Filed: Jan. 27, 2016

(30) Foreign Application Priority Data
Jan. 29, 2015 (JP) 2015-016140

(51) Int. Cl. H01L 33/38; H01L 33/32

(52) U.S. Cl. CPC H01L 33/387; H01L 33/32

(57) ABSTRACT

There is provided a Group III nitride semiconductor light-emitting device with a large light emission amount when a substrate has a rectangular shape. The light-emitting device comprises a rectangular substrate having a first long side, a second long side, a first short side, and a second short side; an n-type contact layer on the substrate; a plurality of n-dot electrodes ND on the n-type contact layer; a first line having a part of the n-dot electrodes ND arranged along the first long side; and a second line having a remaining part of the n-dot electrodes ND arranged along the second long side. A plurality of n-dot electrodes ND belong to either the first line or the second line. The n-dot electrodes ND belonging to the first line and the n-dot electrodes ND belonging to the second line are alternately arranged so as not to oppose each other.

### BACKGROUND OF THE INVENTION

1. Field of the Invention

The present invention relates to a Group III nitride semiconductor light-emitting device, and more specifically to a Group III nitride semiconductor light-emitting device exhibiting an optimized arrangement of dot electrodes.

2. Background Art

Some Group III nitride semiconductor light-emitting devices have a plurality of dot electrodes arranged. As used herein, “dot electrode” encompasses an electrode in contact with a semiconductor layer in a dotted contact region. In a device, a plurality of dot electrodes are provided. The dot electrode has, for example, a circle or polygon contact region. Needless to say, the contact region may have other shape. The dot electrode, for example, includes a circle electrode with a diameter of 50 μm or less. Needless to say, an electrode having other shape with a different diameter may be used. By arranging a plurality of dot electrodes, electric current can be diffused particularly in the p-type semiconductor layer. Therefore, a technique has been developed, in which dot electrodes are discretely arranged on the light-emitting surface.

Japanese Patent Application Laid-Open (kokai) No. 2011-66304 discloses a light-emitting device in which dot electrodes are discretely arranged (refer to FIG. 1).

In a light-emitting device using a rectangular substrate, the light-emitting surface is almost rectangular. In the light-emitting device having a rectangular light-emitting surface, it is not clear which dot electrode pattern is preferable. When the number of dot electrodes is excessively increased, the emission area is decreased. That is, the light emission amount is small.

Particularly when the length of the short sides of the rectangle is small, it is difficult to determine the dot electrode pattern. Since the light-emitting surface has a long narrow shape, the emission area becomes narrow depending on the dot electrode pattern. Therefore, the total radiant flux is preferably ensured without sacrificing the emission area.

### SUMMARY OF THE INVENTION

The present invention has been conceived to solve the foregoing problems in the prior art. It is therefore an object of the present invention to provide a Group III nitride semiconductor light-emitting device exhibiting a large light emission amount in the case of a rectangular substrate.

In a first aspect of the present technique, there is provided a Group III nitride semiconductor light-emitting device, the light-emitting device comprising a rectangular substrate having a first long side, a second long side, a first short side, and a second short side; an n-type semiconductor layer on the substrate; a plurality of n-dot electrodes on the n-type semiconductor layer; a first line having a part of the n-dot electrodes arranged along the first long side; and a second line having a remaining part of the n-dot electrodes arranged along the second long side. A plurality of n-dot electrodes belong to either the first line or the second line. The n-dot electrodes belonging to the first line and the n-dot electrodes belonging to the second line are alternately arranged so as not to oppose each other.

The Group III nitride semiconductor light-emitting device has a plurality of n-dot electrodes. The plurality of n-dot electrodes belong to either the first line or the second line. Therefore, on the light-emitting surface, even if a p-dot electrode is arranged at a position most distant from an n-dot electrode, a distance between the p-dot electrode and the n-dot electrode is comparatively small. Thus, a sufficiently bright light-emitting device is achieved while electric current is effectively diffused.

A second aspect of the technique is directed to a specific embodiment of the Group III nitride semiconductor light-emitting device, wherein the first short side has a length of 400 μm or less.

A third aspect of the technique is directed to a specific embodiment of the Group III nitride semiconductor light-emitting device, wherein a distance between the n-dot electrodes which belong to the first line and are adjacent to each other is constant, and a distance between the n-dot electrodes which belong to the second line and are adjacent to each other is constant.

A fourth aspect of the technique is directed to a specific embodiment of the Group III nitride semiconductor light-emitting device, wherein when a first n-dot electrode and a second n-dot electrode which belong to the first line and are adjacent to each other are projected onto the second line, a third n-dot electrode belonging to the second line is arranged at a center position between the projected first n-dot electrode and the projected second n-dot electrode.

A fifth aspect of the technique is directed to a specific embodiment of the Group III nitride semiconductor light-emitting device, wherein a number of the n-dot electrodes belonging to the first line is an odd number, and a number of the n-dot electrodes belonging to the second line is an even number.

A sixth aspect of the technique is directed to a specific embodiment of the Group III nitride semiconductor light-emitting device, wherein a plurality of p-dot electrodes are provided, and the number of the p-dot electrodes is larger than that of the n-dot electrodes.

A seventh aspect of the technique is directed to a specific embodiment of the Group III nitride semiconductor light-emitting device, wherein the length of the first long side is twice or more the length of the first short side.

An eighth aspect of the technique is directed to a flip-chip type Group III nitride semiconductor light-emitting device.

The present technique, disclosed in the specification, provide a Group III nitride semiconductor light-emitting device with a large light emission amount when a substrate has a rectangular shape.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a plan view showing the structure of a light-emitting device according to Embodiment 1;

FIG. 2 is a cross-sectional view showing the II-II cross-section of FIG. 1;

FIG. 3 is a plan view showing dot electrode pattern B;

FIG. 4 is a plan view showing dot electrode pattern C;

FIG. 5 is a plan view showing dot electrode pattern D;

FIG. 6 is a sketch for describing a distance between p-dot electrode and n-dot electrode in the dot electrode pattern A;

FIG. 7 is a sketch for describing a distance between p-dot electrode and n-dot electrode in the dot electrode pattern B;

FIG. 8 is a sketch for describing a distance between p-dot electrode and n-dot electrode in the dot electrode pattern C; and

FIG. 9 is a sketch for describing a distance between p-dot electrode and n-dot electrode in the dot electrode pattern D.

### DETAILED DESCRIPTION OF PREFERRED EMBODIMENT

A specific exemplary embodiment of the semiconductor light-emitting device will next be described with reference to the drawings. However, the present invention is not limited to the embodiment. The layered structure and electrode structure of the semiconductor light-emitting device described later are examples only. Any layered structure different from that in the embodiment may be employed. The thicknesses of layers shown in the drawings are conceptual and are not their actual thicknesses.

### Embodiment 1

1. Semiconductor Light-emitting Device

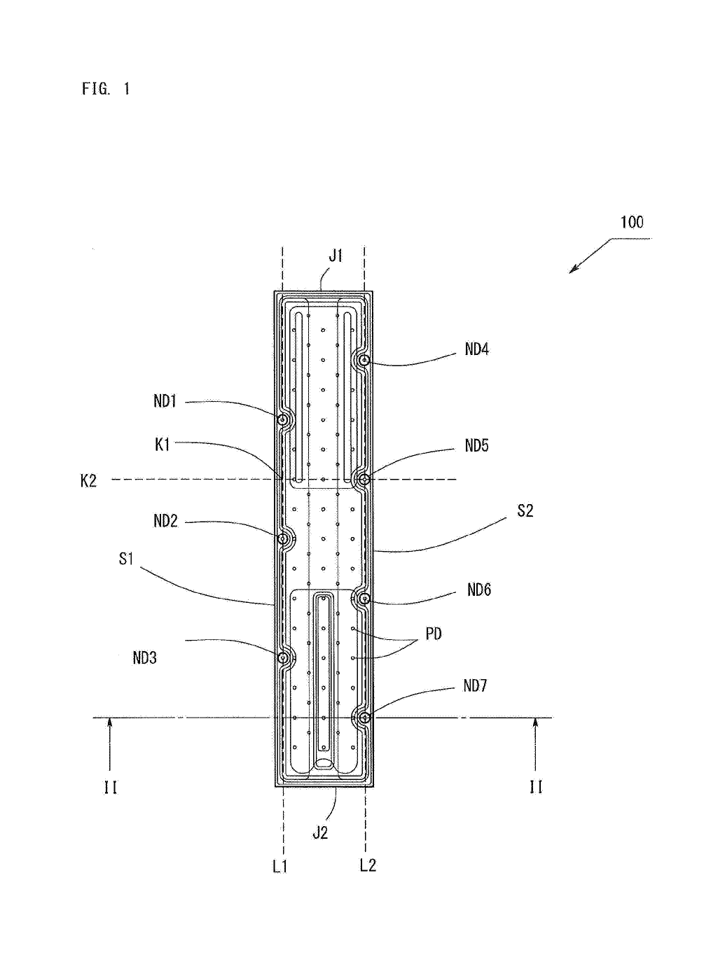

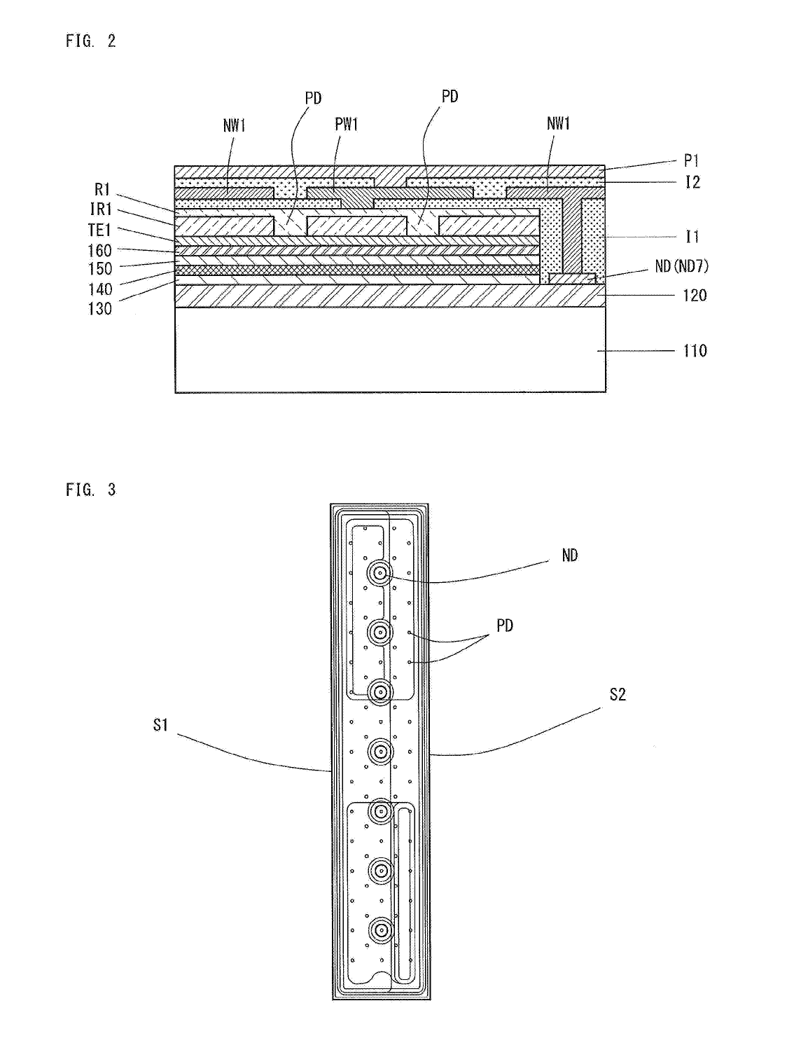

FIG. 1 is a plan view showing the structure of a light-emitting device 100 according to Embodiment 1. FIG. 2 is a cross-sectional view showing the II-II cross-section of FIG. 1. The light-emitting device 100 is a flip-chip type semiconductor light-emitting device. As shown in FIG. 2, the light-emitting device 100 comprises a substrate 110, an n-type contact layer 120, an n-side cladding layer 130, a light-emitting layer 140, a p-side cladding layer 150, a p-type contact layer 160, an n-dot electrode ND (ND7), a transparent electrode TE1, an insulating reflective layer IR1, a reflective layer R1, insulating layers I1 and I2, a p-wiring electrode PW1, an n-wiring electrode NW1, and a p-electrode P1.

The substrate 110 is a sapphire substrate. The light emitted from the light-emitting layer 140 is transmitted therethrough to a side opposite to the semiconductor layers. The substrate 110 has a rectangular shape. The substrate 110 has a first long side S1, a second long side S2, a first short side J1, and a second short side J2. Needless to say, the length of the first long side S1 is equal to that of the second long side S2. The length of the first short side J1 is equal to that of the second short side J2. The length of the first short side J1 and the second short side J2 is within a range of 100 μm to 400 μm. The length of the first long side S1 is two times to five times that of the first short side J1.

The n-type contact layer 120 is a semiconductor layer to make contact with the n-dot electrode ND. The n-type contact layer 120 is formed on the substrate 110. A buffer layer (not illustrated) is preferably provided between the substrate 110 and the n-type contact layer 120. The n-side cladding layer 130 is formed on the n-type contact layer 120. The n-type contact layer 120 and the n-side cladding layer 130 are n-type semiconductor layers.

The light-emitting layer 140 is a semiconductor layer to recombine holes and electrons for light emission. The light-emitting layer 140 is formed on the n-side cladding layer 130.

The p-side cladding layer 150 is formed on the light-emitting layer 140. The p-type contact layer 160 is a semiconductor layer to make contact with the transparent electrode TE1. The p-type contact layer 160 is formed on the p-side cladding layer 150. The p-side cladding layer 150 and the p-type contact layer 160 are p-type semiconductor layers.

A plurality of n-dot electrodes ND (ND7) are electrodes to make contact with the n-type contact layer 120. The codes of ND1, ND2, ND3, ND4, ND5, ND6, and ND7 are assigned to the n-dot electrodes ND according to the arranged position. However, when the positions of the n-dot electrodes do not matter, the n-dot electrodes are collectively described as ND. The n-dot electrodes ND are formed on the n-type contact layer 120. The n-dot electrode ND is made of a material such as Ti, Ni, and Cr. In order to increase the reflectance, Al, Ag, Rh, or alloy containing these may be used. Needless to say, other materials may be used.

The transparent electrode TE1 is an electrode to make contact with the p-type contact layer 160. The transparent electrode TE1 is formed on the p-type contact layer 160. The transparent electrode TE1 is made of ITO. Instead of ITO, a transparent conductive oxide such as ICO, IZO, ZnO, TiO₂, NbTiO₂, and TaTiO₂ may be used.

The insulating reflective layer IR1 is an insulating reflective layer. The insulating reflective layer IR1 is formed on the transparent electrode TE1. The insulating reflective layer IR1 has a plurality of through holes. The insulating reflective layer IR1 is a DBR film having, for example, a multilayer of SiO₂ and TiO₂ alternately deposited. The layer IR1 may be a single layer of SiO₂. Needless to say, other materials may be used.

The reflective layer R1 is a conductive reflective layer. The reflective layer R1 is formed on the transparent electrode TE1 and the insulating reflective layer IR1. The reflective layer R1 is in contact with the transparent electrode TE1 at the through holes of the insulating reflective layer IR1. Therefore, the through holes filled with the material of the reflective layer R1 are the p-dot electrodes PD. The reflective layer R1 is made of a material such as Al, Ag, and Rh, or alloy containing these. Needless to say, other materials may be used.

A plurality of p-dot electrodes PD are a part of the reflective layer R1. A plurality of p-dot electrodes PD are electrodes to be electrically conducted with the p-type contact layer 160. A plurality of the p-dot electrodes PD are dispersively arranged on the light-emitting surface. The number of the p-dot electrodes PD is larger than that of the n-dot electrodes ND.

The insulating layers I1 and I2 are provided to insulate between the n-wiring electrode NW1 and the p-wiring electrode PW1. Therefore, the insulating layer I2 is formed so as to cover the n-wiring electrode NW1. The n-wiring electrode NW1 is a wiring electrode to electrically connect the n-dot electrodes ND. The n-wiring electrode NW1 is in contact with the n-dot electrode ND. The p-wiring electrode PW1 is a wiring electrode to electrically connect the p-dot electrodes PD. The p-electrode P1 is a land electrode to be actually bonded to an external circuit when mounting. The p-electrode P1 is formed on the p-wiring electrode PW1. The insulating layers I1 and I2 are made of a material such as SiO₂. Needless to say, other materials may be used.

2. Arrangement of n-dot Electrodes

As shown in FIG. 1, the light-emitting device 100 has seven n-dot electrodes ND1, ND2, ND3, ND4, ND5, ND6, and ND7. The light-emitting device 100 has a first line L1 of the n-dot electrodes ND, and a second line L2 of the n-dot electrodes ND.

In the first line L1, some of the n-dot electrodes ND are arranged along the first long side S1. The first line L1 has the n-dot electrodes ND1, ND2, and ND3. That is, the first line L1 has three, in other words, an odd number of n-dot electrodes. The n-dot electrodes ND1, ND2, and ND3 belong to the first line L1.

In the second line L2, the others of the n-dot electrodes ND are arranged along the second long side S2. The second line L2 has the n-dot electrodes ND4, ND5, ND6, and ND7. That is, the second line L2 has four, in other words, an even number of n-dot electrodes. The n-dot electrodes ND4, ND5, ND6, and ND7 belong to the second line L2.

A distance between the n-dot electrodes ND which belong to the first line L1 and are adjacent to each other is constant. A distance between the n-dot electrodes ND which belong to the second line L2 and are adjacent to each other is constant.

A plurality of the n-dot electrodes ND belong to either the first line L1 or the second line L2. The n-dot electrodes ND belonging to the first line L1 and the n-dot electrodes ND belonging to the second line L2 are alternately arranged so as not to oppose each other.

For example, the center position between the n-dot electrode ND1 belonging to the first line L1 and the n-dot electrode ND2 belonging to the first line L1 is a point K1. The n-dot electrode ND5 is disposed at a position which a perpendicular line K2 dropped from the point K1 toward the second line L2 intersects the second line L2.

That is, in the case when the first n-dot electrode ND and the second n-dot electrode ND belonging to the first line L1 and being adjacent to each other are projected onto the second line L2, the third n-dot electrode ND belonging to the second line L2 is disposed at the center position between the projected first n-dot electrode ND and the projected second n-dot electrode ND.

3. Effect of the Present Embodiment

In this way, the light-emitting device 100 has n-dot electrodes ND alternately arranged in the first line L1 and the second line L2 on the rectangular substrate 110. Such arrangement makes an average of main current paths shorter in pairs of the n-dot electrode ND and the p-dot electrode PD. As a result, the drive voltage of the light-emitting device can be reduced. Moreover, the periphery of the light-emitting device is an area where the luminance is small or no light is emitted. Since the n-dot electrodes ND are disposed on the outer circumference of the light-emitting surface, the n-dot electrodes ND do not sacrifice an effective light-emitting area so much. That is, in the light-emitting device 100, a large effective light-emitting area is ensured. And, the light-emitting device 100 can uniformly emit light from the entire light-emitting surface.

4. Experiment

Next will be described the experiment of the light-emitting device 100 according to Embodiment 1. In the experiment, with the n-dot electrodes ND arranged in different patterns, total radiant flux Po, drive voltage Vf, and emission efficiency were compared.

4-1. Dot Electrode Pattern

In the experiment, a dot electrode pattern A, a dot electrode pattern B, a dot electrode pattern C, and a dot electrode pattern D were considered.

FIG. 1 shows the dot electrode pattern A. The dot electrode pattern A is the electrode arrangement according to Embodiment 1. That is, the dot electrode pattern A has the first line L1 and the second line L2, and the n-dot electrodes ND of the first line L1 and the n-dot electrodes ND of the second line L2 are alternately arranged so as not to oppose each other.

FIG. 3 shows the dot electrode pattern B. The dot electrode pattern B has only the first line. The first line is disposed along the center line between the first long side S1 and the second long side S2. That is, the n-dot electrodes ND are arranged along the center line.

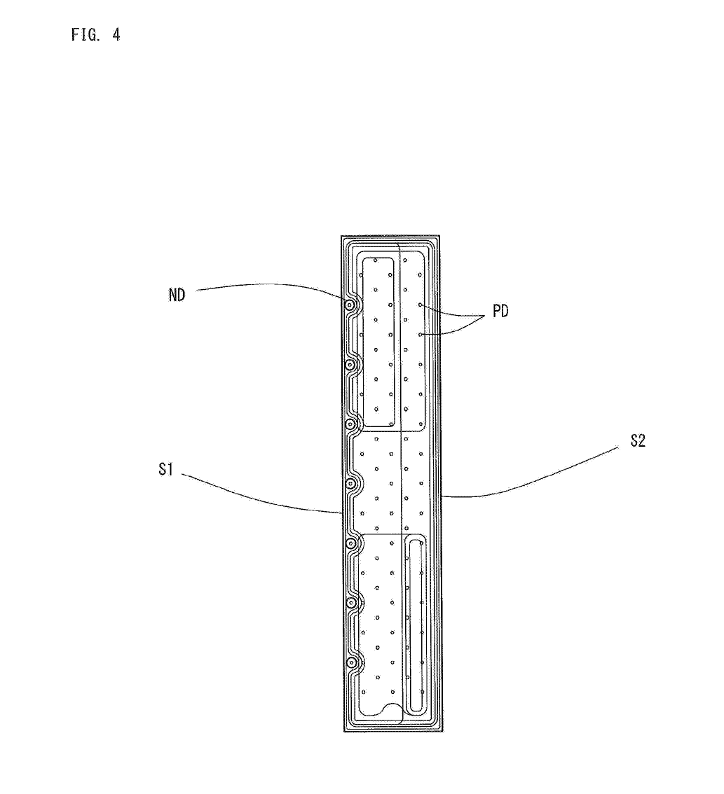

FIG. 4 shows the dot electrode pattern C. The dot electrode pattern C has only the first line. The first line is disposed along the first long side S1. That is, the n-dot electrodes ND are arranged along the first long side S1. There is no n-dot electrode ND on the second long side S2.

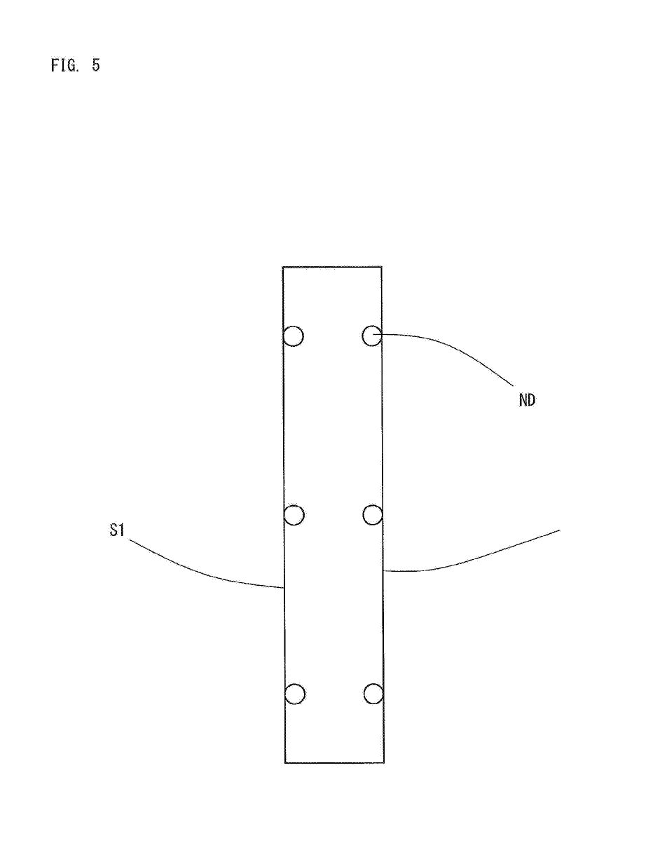

FIG. 5 shows the dot electrode pattern D. The dot electrode pattern D has the first line and the second line. When the first line is projected onto the second line, the positions of the n-dot electrodes ND in the first line are overlapped with the positions of the n-dot electrodes ND in the second line.

4-2. Distance Between Dot Electrodes

Table 1 shows the patterns of n-dot electrodes ND and the characteristics. As shown in FIG. 6, in the dot electrode pattern A, the n-dot electrodes ND are arranged on the low-luminance outer circumference of the light-emitting surface. Therefore, one n-dot electrodes ND do not occupy a large effective light-emitting area. Thus, a large light-emitting area is ensured in the light-emitting device having the dot electrode pattern A. The n-dot electrodes closest to each of the p-dot electrodes PD are determined, and pairs of the p-dot electrode and the n-dot electrode are made. The maximum value of the distance between the p-dot electrode and the n-dot electrode in each pair is defined as a distance between the p-dot electrode and the n-dot electrode. More specifically, it will be described with reference to FIGS. 6 to 9. In FIGS. 6 to 9, the short side a of the light-emitting device and the half widths b of the distance between the dot electrodes are indicated.

As shown in FIG. 7, in the dot electrode pattern B, the n-dot electrodes ND are arranged along the high-luminance center line of the light-emitting surface. Therefore, the effective light-emitting area occupied by one n-dot electrode ND is larger than that in the dot electrode patterns A and C. The effective light-emitting area of the light-emitting device having the dot electrode pattern B is smaller than those of the light-emitting devices having the dot electrode patterns A and C. The distance between the p-dot electrode and the n-dot electrode in the dot electrode pattern B tends to be smaller than that in the dot electrode pattern A.

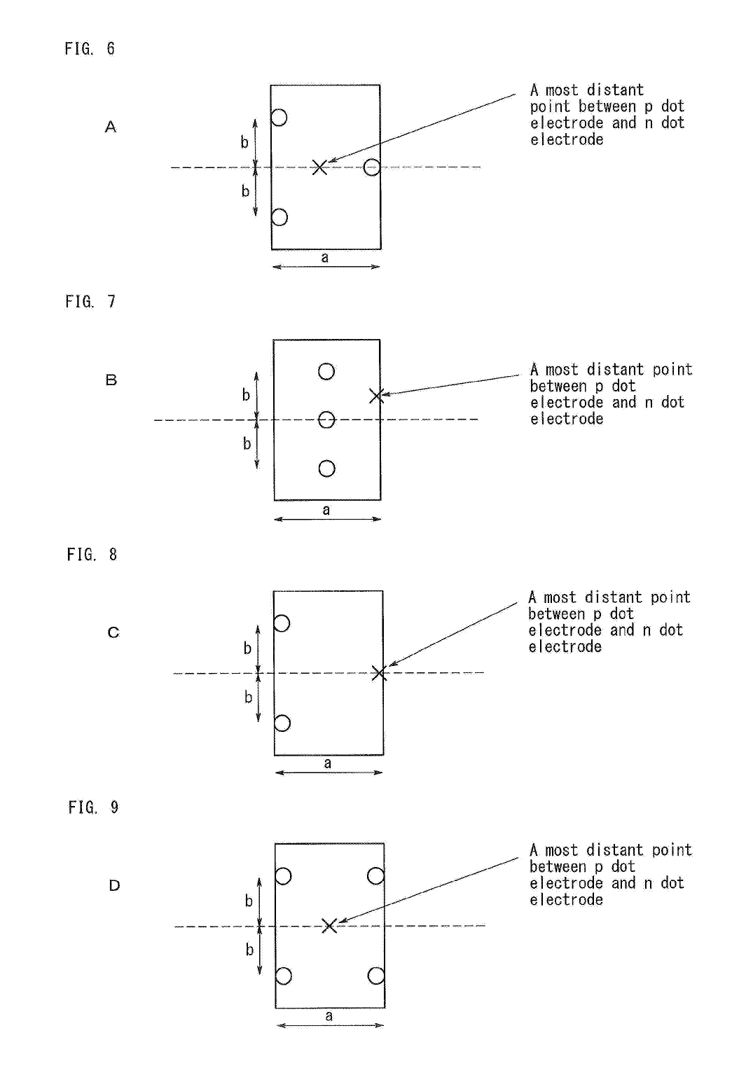

As shown in FIG. 8, in the dot electrode pattern C, similarly to the dot electrode pattern A, the n-dot electrodes ND are arranged at the end of the light-emitting surface. Therefore, one n-dot electrode ND does not occupy a large effective light-emitting area. Thus, a large effective light-emitting area is ensured in the light-emitting device having the dot electrode pattern C. However, the distance between the p-dot electrode and the n-dot electrode in the dot electrode pattern C is larger than that in the dot electrode pattern A. Therefore, the drive voltage Vf of the light-emitting device having the dot electrode pattern C is higher than that of the light-emitting device having the electrode pattern A, which is not preferable. In addition, the n-dot electrodes ND are not uniformly arranged on the entire light-emitting surface. Therefore, the light-emitting device having the dot electrode pattern C emits light a little nonuniformly.

As shown in FIG. 9, the dot electrode pattern D is similar to the dot electrode pattern A. Since the n-dot electrodes ND are arranged at the end of the light-emitting surface, one n-dot electrode ND does not occupy a large effective light-emitting area in the dot electrode pattern D. Therefore, a large effective light-emitting area is ensured in the light-emitting device having the dot electrode pattern D. However, since the distance between the p-doe electrode and the n-dot electrode in the dot electrode pattern D is larger than that in the dot electrode pattern A, the drive voltage Vf in the dot electrode pattern D is higher than that in the dot electrode pattern A. Thus, the dot electrode pattern A is more preferably than the dot electrode pattern D.

TABLE 1

| | A | B | C | D |
|---|---|---|---|---|
| Electrode | Seven n-dot | Seven n-dot | Seven dot | Six dot |
| pattern | electrodes | electrodes | electrodes | electrodes |
| | alternately | arranged | arranged at | symmetrically |
| | arranged at | along the | one end | arranged at |
| | both ends | center line | | both ends |
| Light- | Large | Small | Large | Large |
| emitting | | | | |
| area (→ Po) | | | | |
| Distance | Small | Very small | Large | Large |
| between | | | | |
| p-dot | | | | |
| electrode | | | | |
| and n-dot | | | | |
| electrode | | | | |
| (→ Vf) | | | | |

4-3. Measurement Results

Table 2 shows the measurement results. In the dot electrode pattern A, the total radiant flux Po was 29.53 (mW), and the drive voltage Vf was 2.80 (V). The emission efficiency was 52.7%. As used herein, the efficiency (%) refers to an ratio of output power (mW) to electric power (mW) applied to the light-emitting device 100.

In the dot electrode pattern B, the total radiant flux Po was 28.96 (mW), and the drive voltage Vf was 2.80(V). The emission efficiency was 51.7%.

In the dot electrode pattern C, the total radiant flux Po was 29.56 (mW), and the drive voltage Vf was 2.81(V). The emission efficiency was 52.6%.

For the dot electrode pattern D, measurement was not performed.

As described above, in the dot electrode patterns A and C, the total radiant flux and the emission efficiency were higher than those in the dot electrode pattern B. In the light-emitting device having the dot electrode pattern A, light is more uniformly emitted from the entire light-emitting surface than in the light-emitting device having the dot electrode pattern C. Therefore, the dot electrode pattern A is most preferable.

TABLE 2

| | | A | B | C | D |
|---|---|---|---|---|---|
| Tester results | Po_medium | 29.53 | 28.96 | 29.56 | Not |
| after separation | Vf_medium | 2.80 | 2.80 | 2.81 | performed |
| | Efficiency | 52.7% | 51.7% | 52.6% | |

5. Variations

5-1. Definition of Line

In the present embodiment, the first line L1 has three n-dot electrodes, and the second line L2 has four n-dot electrodes. However, the first line L1 and the second line L2 are just a matter of definition, and may be exchanged. That is, the first line L1 may have four n-dot electrodes and the second line L2 may have three n-dot electrodes. Each of the first line L1 and the second line L2 may have a different number of n-dot electrodes from the number of the n-dot electrodes shown in FIG. 1.

5-2. Face-up Type

The light-emitting device 100 according to the present embodiment is a flip-chip type semiconductor light-emitting device. However, the technique of the present embodiment may be applied to a face-up type light-emitting device.

6. Summary of the Present Embodiment

As described above, the light-emitting device 100 according to the present embodiment is a semiconductor light-emitting device having a plurality of n-dot electrodes ND. In the light-emitting device 100, a substrate 110 has a rectangular shape. The rectangular substrate 110 has a short side with a length of 400 μm or less. The light-emitting device 100 has a first line L1 along the first long side S1 and a second line L2 along the second long side S2. The n-dot electrodes ND belonging to the first line L1 and the n-dot electrodes ND belonging to the second line L2 are alternately arranged so as not to oppose each other. Therefore, a bright light-emitting device 100 is achieved while the light emitting area is ensured.

The aforementioned embodiment is merely an example. It is therefore understood that those skilled in the art can provide various modifications and variations of the technique, so long as those fall within the scope of the present technique. The stacking structure of semiconductor layer or wiring should not be limited to those as illustrated, and the stacking structure, the thickness, and other factors may be arbitrarily chosen. The method for producing a light-emitting device 100 is not limited to metalorganic chemical vapor deposition (MOCVD), and other vapor phase epitaxy techniques and other liquid-phase epitaxy techniques may also be employed.

What is claimed is:

1. A Group III nitride semiconductor light-emitting device, the light-emitting device comprising:
a rectangular substrate having a first long side, a second long side, a first short side, and a second short side;
an n-type semiconductor layer on the substrate;
a plurality of n-dot electrodes on the n-type semiconductor layer;
a first line having a part of the n-dot electrodes arranged along the first long side; and
a second line having a remaining part of the n-dot electrodes arranged along the second long side;
wherein the n-dot electrodes belong to either the first line or the second line; and
the n-dot electrodes belonging to the first line and the n-dot electrodes belonging to the second line are alternately arranged so as not to oppose each other.

2. The Group III nitride semiconductor light-emitting device according to claim 1, wherein the first short side has a length of 400 μm or less.

3. The Group III nitride semiconductor light-emitting device according to claim 1, wherein a distance between the n-dot electrodes which belong to the first line and are adjacent to each other is constant; and
a distance between the n-dot electrodes which belong to the second line and are adjacent to each other is constant.

4. The Group III nitride semiconductor light-emitting device according to claim 2, wherein a distance between the n-dot electrodes which belong to the first line and are adjacent to each other is constant; and
a distance between the n-dot electrodes which belong to the second line and are adjacent to each other is constant.

5. The Group III nitride semiconductor light-emitting device according to claim 1, wherein when the first n-dot electrode and the second n-dot electrode which belong to the first line and are adjacent to each other are projected onto the second line, a third n-dot electrode belonging to the second line is arranged at a center position between the projected first n-dot electrode and the projected second n-dot electrode.

6. The Group III nitride semiconductor light-emitting device according to claim 2, wherein when the first n-dot electrode and the second n-dot electrode which belong to the first line and are adjacent to each other are projected onto the second line, a third n-dot electrode belonging to the second line is arranged at a center position between the projected first n-dot electrode and the projected second n-dot electrode.

7. The Group III nitride semiconductor light-emitting device according to claim 3, wherein when the first n-dot electrode and the second n-dot electrode which belong to the first line and are adjacent to each other are projected onto the second line, a third n-dot electrode belonging to the second line is arranged at a center position between the projected first n-dot electrode and the projected second n-dot electrode.

8. The Group III nitride semiconductor light-emitting device according to claim 1, wherein a number of the n-dot electrodes belonging to the first line is an odd number, and a number of the n-dot electrodes belonging to the second line is an even number.

9. The Group III nitride semiconductor light-emitting device according to claim 2, wherein a number of the n-dot electrodes belonging to the first line is an odd number, and a number of the n-dot electrodes belonging to the second line is an even number.

10. The Group III nitride semiconductor light-emitting device according to claim 4, wherein a number of the n-dot electrodes belonging to the first line is an odd number, and a number of the n-dot electrodes belonging to the second line is an even number.

11. The Group III nitride semiconductor light-emitting device according to claim 5, wherein a number of the n-dot electrodes belonging to the first line is an odd number, and a number of the n-dot electrodes belonging to the second line is an even number.

12. The Group III nitride semiconductor light-emitting device according to claim 1, wherein a plurality of p-dot electrodes are provided, and a number of the p-dot electrodes is larger than that of the n-dot electrodes.

13. The Group III nitride semiconductor light-emitting device according to claim 2, wherein a plurality of p-dot electrodes are provided, and a number of the p-dot electrodes is larger than that of the n-dot electrodes.

14. The Group III nitride semiconductor light-emitting device according to claim 4, wherein a plurality of p-dot electrodes are provided, and a number of the p-dot electrodes is larger than that of the n-dot electrodes.

15. The Group III nitride semiconductor light-emitting device according to claim 5, wherein a plurality of p-dot electrodes are provided, and a number of the p-dot electrodes is larger than that of the n-dot electrodes.

16. The Group III nitride semiconductor light-emitting device according to claim 8, wherein a plurality of p-dot electrodes are provided, and a number of the p-dot electrodes is larger than that of the n-dot electrodes.

17. The Group III nitride semiconductor light-emitting device according to claim 1, wherein a length of the first long side is twice or more a length of the first short side.

18. The Group III nitride semiconductor light-emitting device according to claim 5, wherein a length of the first long side is twice or more a length of the first short side.

19. The Group III nitride semiconductor light-emitting device according to claim 12, wherein a length of the first long side is twice or more a length of the first short side.

20. The Group III nitride semiconductor light-emitting device according to claim 1, wherein the Group III nitride semiconductor light-emitting device is of a flip-chip type.
